(19) United States
(12) Patent Application Publication
(10) Pub. No.: US 2015/0181708 A1
(43) Pub. Date: Jun. 25, 2015

(54) SEMICONDUCTOR PACKAGE MODULE

(71) Applicant: SAMSUNG ELECTRO-MECHANICS CO., LTD., Suwon-Si (KR)

(72) Inventors: Jong In Ryu, Suwon-Si (KR); Eun Jung Jo, Suwon-Si (KR); Do Jae Yoo, Suwon-Si (KR)

(73) Assignee: SAMSUNG ELECTRO-MECHANICS CO., LTD., Suwon-Si (KR)

(21) Appl. No.: 14/268,156

(22) Filed: May 2, 2014

(30) Foreign Application Priority Data
Dec. 20, 2013 (KR) 10-2013-0160451

(51) Int. Cl. H05K 1/11

(52) U.S. Cl. CPC H05K 1/111; H05K 2201/10015

(57) ABSTRACT

There is provided a semiconductor package module including: a substrate having one or more connection terminals formed thereon; first electronic components mounted on a first surface of the substrate; second electronic components mounted on a second surface of the substrate; and third electronic components formed on the substrate and including connection electrodes connecting the one or more connection terminals and external terminals to each other.

### CROSS-REFERENCE TO RELATED APPLICATION

This application claims the benefit of Korean Patent Application No. 10-2013-0160451 filed on Dec. 20, 2013, with the Korean Intellectual Property Office, the disclosure of which is incorporated herein in its entirety by reference.

### BACKGROUND

The present technology generally relates to a semiconductor package module having electronic components mounted on both surfaces thereof.

In accordance with demand for portable electronic devices such as portable communications devices, portable computer, portable games machines, and the like, demand for small semiconductor package modules has increased. Further, in accordance with the miniaturization and thinning of portable electronic devices, demand for miniaturization and thinning of semiconductor package modules has increased.

There are three main improvement structures or improvement methods for the miniaturization of semiconductor package modules.

One is to decrease a gap between electronic components mounted on a substrate. Such a structure has an advantage in that a size of the semiconductor package module may be decreased while maintaining an existing design structure. However, this structure may be difficult to use in the case in which shapes and sizes of electronic components are different from each other and has a limitation in terms of significantly decreasing a size of the semiconductor package module.

Another is to accommodate some electronic components within the substrate. Such a structure is advantageous in miniaturizing and packaging the semiconductor package module, since the electronic components may be mounted in a distributed space. However, this structure has disadvantages in that it is significantly affected by a manufacturing yield of the substrate and manufacturing costs for the substrate are increased.

The third is to mount the electronic components on both surfaces of the substrate. Such a structure is advantageous in significantly decreasing a size of a cross section of the substrate since a plurality of electronic components may be dispersively disposed on both surfaces of the substrate. However, this structure has disadvantages that a thickness of the substrate may be increased along with an electrical signal distance of an output terminal.

### SUMMARY

Some embodiments of the present disclosure may provide a semiconductor package module capable of solving disadvantages of a double-sided substrate structure.

According to some embodiments of the present disclosure, a semiconductor package module may include: a substrate having one or more connection terminals formed thereon; first electronic components mounted on a first surface of the substrate; second electronic components mounted on a second surface of the substrate; and third electronic components formed on the substrate and including connection electrodes connecting the one or more connection terminals and external terminals to each other.

The connection terminals may be formed in plural rows along an edge of the second surface.

The connection terminal may be a ground electrode terminal.

The connection terminal may be a power supplying terminal.

The connection terminal may be an input/output signal terminal.

The connection terminal may be a radio frequency signal terminal.

The third electronic component may be a passive element.

The third electronic component may be a multilayer ceramic capacitor.

The third electronic components may be connected to a plurality of connection terminals, respectively.

The third electronic components may include a plurality of connection electrodes connected to a plurality of connection terminals, respectively.

The connection electrode may be a via electrode penetrating through a body of a third electronic component among the third electronic components.

The connection electrode may be an external electrode formed on a surface of a third electronic component among the third electronic components.

The semiconductor package module may further include a molded member covering the first and second electronic components.

According to some embodiments of the present disclosure, a semiconductor package module may include: a substrate having one or more connection terminals formed thereon; first electronic components mounted on a first surface of the substrate; second electronic components mounted on a second surface of the substrate; third electronic components including first connection electrodes connected to the one or more connection terminals; and fourth electronic components formed on the third electronic components and including second connection electrodes connecting the first connection electrodes and external electrodes to each other.

The connection terminal may be a ground electrode terminal.

The connection terminal may be a power supplying terminal.

The connection terminal may be an input/output signal terminal.

The connection terminal may be a radio frequency signal terminal.

The third and fourth electronic components may be passive elements.

At least one of the third and fourth electronic components may be a multilayer ceramic capacitor.

The third electronic components may be connected to a plurality of connection terminals, respectively.

The third electronic components may include a plurality of first connection electrodes connected to a plurality of connection terminals, respectively.

A plurality of fourth electronic components may be formed on the third electronic components, respectively, so as to be connected to the plurality of first connection electrodes, respectively.

The first connection electrode may be a first via electrode penetrating through a body of a third electronic component among the third electronic components, and the second connection electrode may be a second via electrode penetrating through a body of the fourth electronic component.

The first connection electrode may be a first external electrode formed on a surface of a third electronic component among the third electronic components, and the second connection electrode may be a second external electrode formed along a surface of the fourth electronic component.

The semiconductor package module may further include a molded member covering the first and second electronic components.

A height of the third electronic component or a height of the fourth electronic component may be lower than a height of the first electronic component or a height of the second electronic component.

A sum of a height of the third electronic component and a height of the fourth electronic component may be higher than a height of the first electronic component or a height of the second electronic component.

The first and second electronic components may be formed in a circuit pattern area of the substrate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of a semiconductor package module according to an exemplary embodiment of the present disclosure;

FIG. 2 is a plan view of the semiconductor package module shown in FIG. 1;

FIG. 3 is a bottom view of the semiconductor package module shown in FIG. 1;

FIGS. 4 through 6 are bottom views of the semiconductor package module showing another disposition form of a third electronic component;

FIGS. 7 and 8 are views showing another form of a connection electrode of the third electronic component;

FIG. 9 is a cross-sectional view showing another form of the semiconductor package module shown in FIG. 1;

FIG. 10 is a cross-sectional view of a semiconductor package module according to another exemplary embodiment of the present disclosure;

FIGS. 11 and 12 are bottom perspective views showing various coupling structures between third and fourth electronic components; and

FIG. 13 is a cross-sectional view showing another form of the semiconductor package module shown in FIG. 10.

### DETAILED DESCRIPTION

Exemplary embodiments of the present disclosure will now be described in detail with reference to the accompanying drawings.

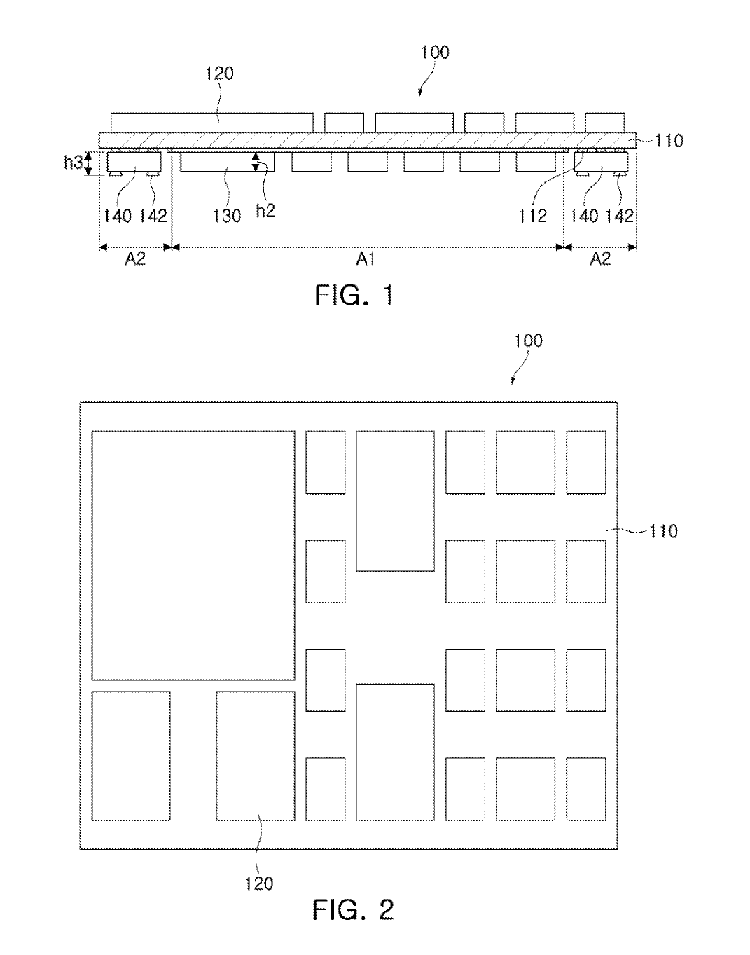

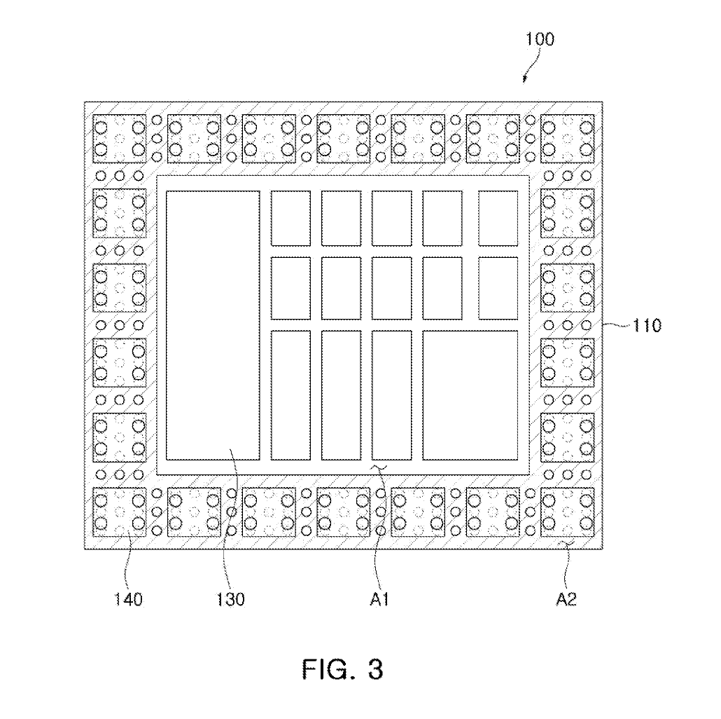

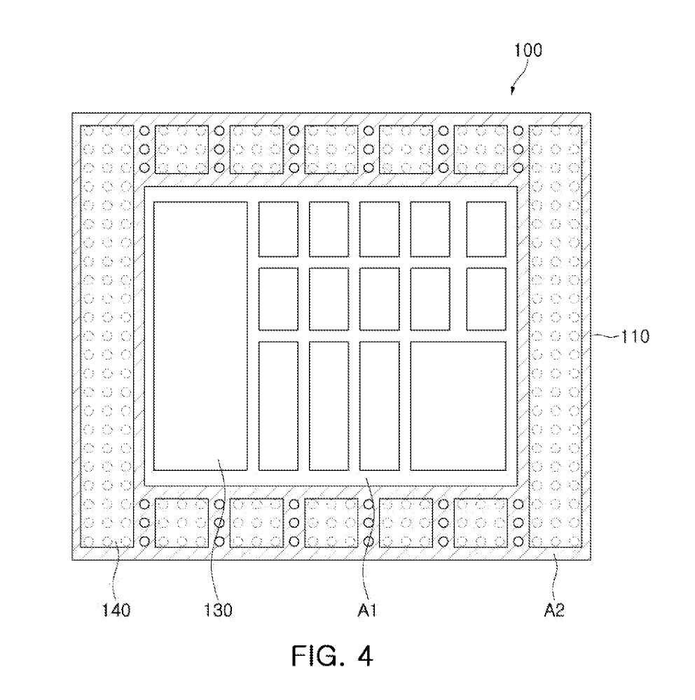

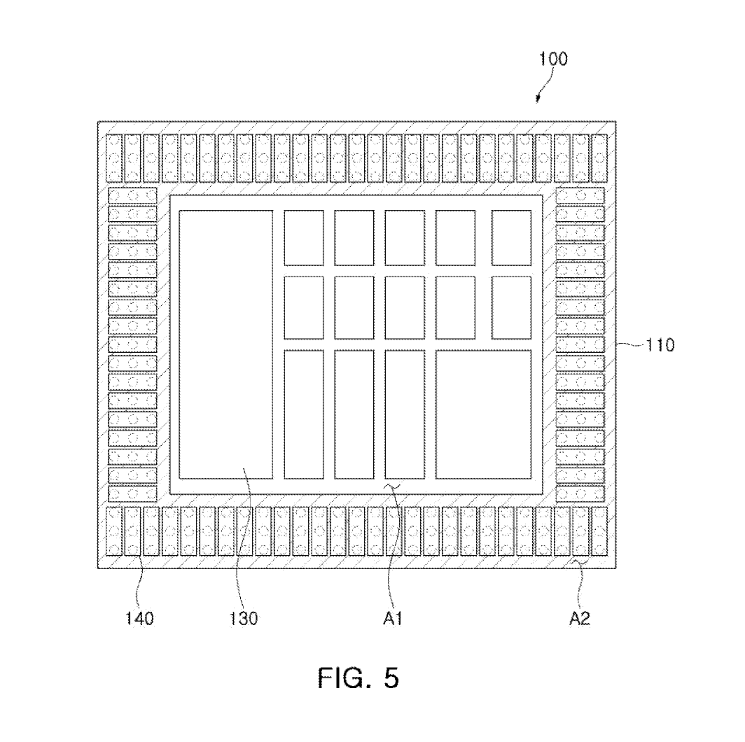

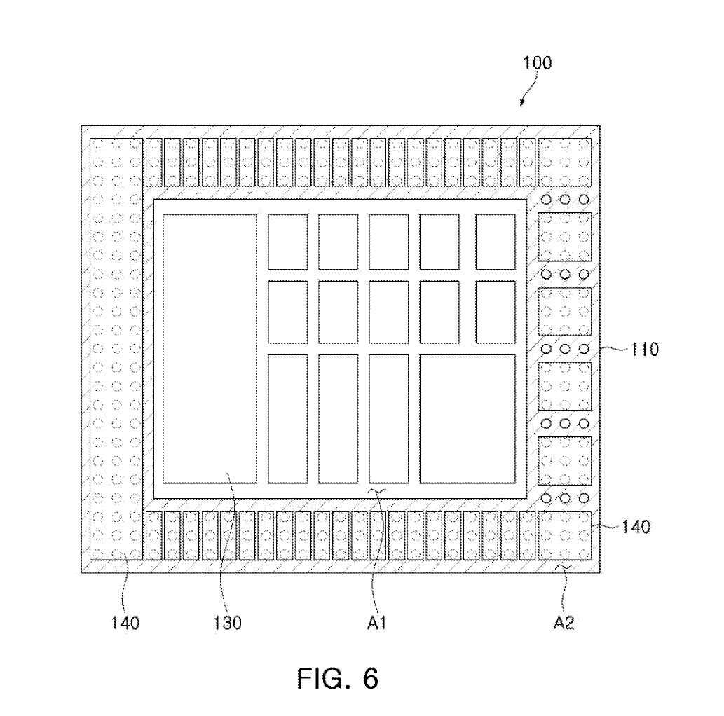

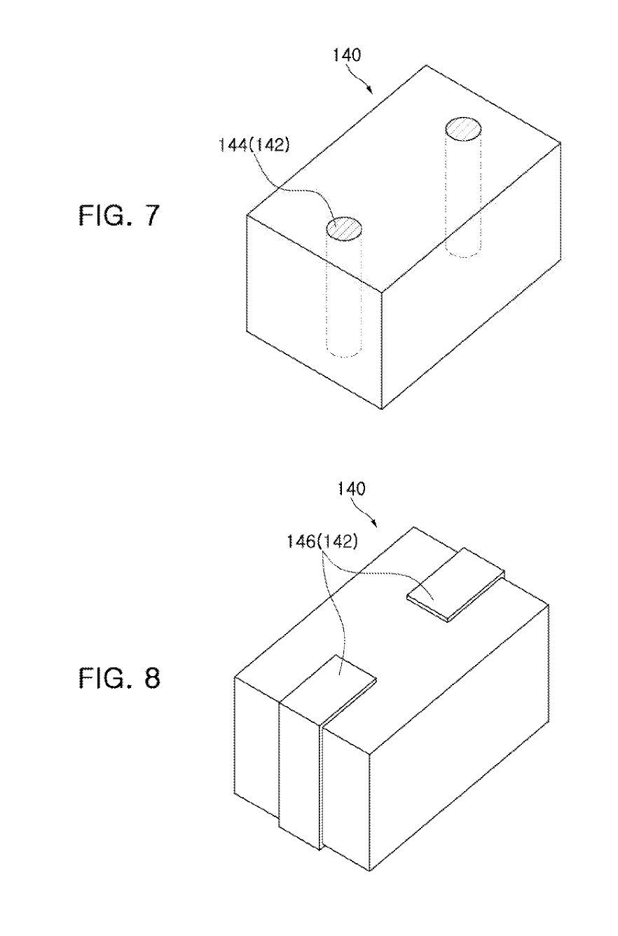

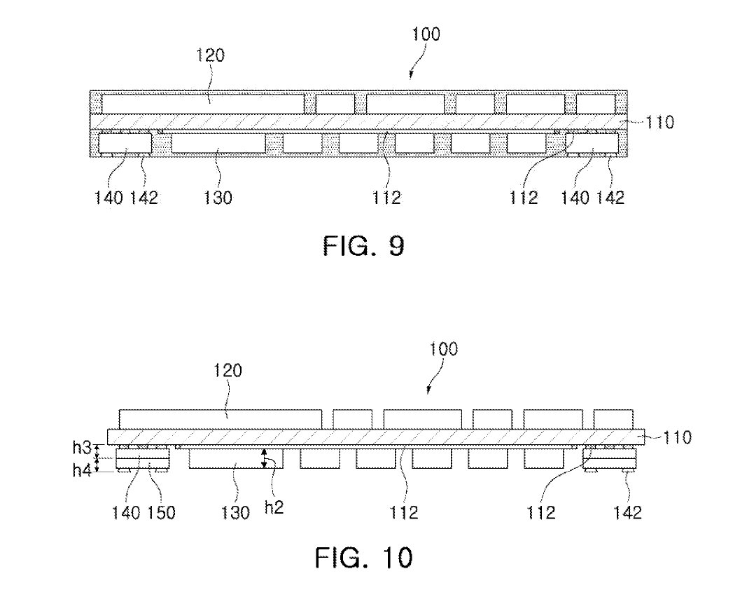

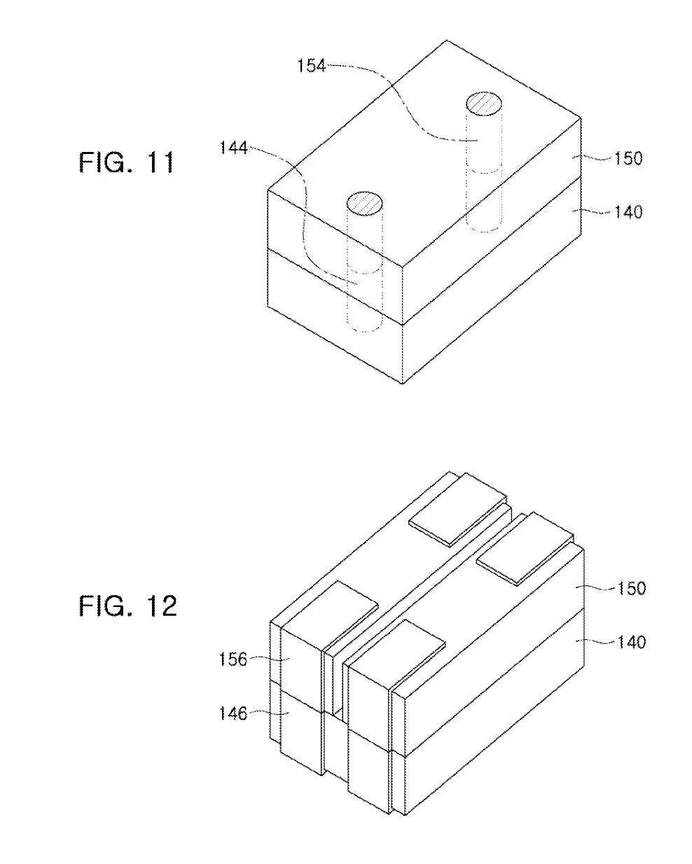

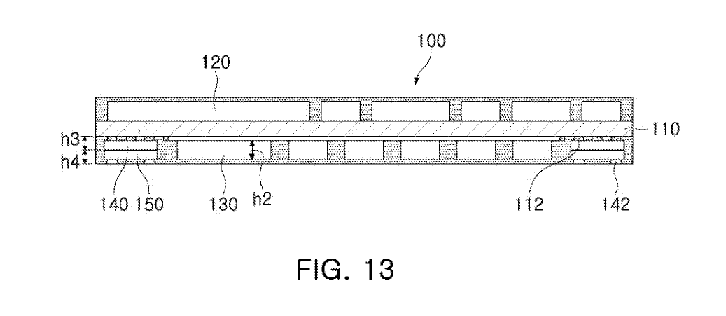

FIG. 1 is a cross-sectional view of a semiconductor package module according to an exemplary embodiment of the present disclosure; FIG. 2 is a plan view of the semiconductor package module shown in FIG. 1; FIG. 3 is a bottom view of the semiconductor package module shown in FIG. 1; FIGS. 4 through 6 are bottom views of the semiconductor package module showing another disposition form of a third electronic component; FIGS. 7 and 8 are views showing another form of a connection electrode of the third electronic component; FIG. 9 is a cross-sectional view showing another form of the semiconductor package module shown in FIG. 1; FIG. 10 is a cross-sectional view of a semiconductor package module according to another exemplary embodiment of the present disclosure; FIGS. 11 and 12 are bottom perspective views showing various coupling structures between third and fourth electronic components; and FIG. 13 is a cross-sectional view showing another form of the semiconductor package module shown in FIG. 10.

A semiconductor package module according to an exemplary embodiment of the present disclosure will be described with reference to FIGS. 1 through 3.

The semiconductor package module 100 may include a substrate 110, first electronic components 120, and second electronic components 130. In addition, the semiconductor package module 100 may include third electronic components 140. Further, the semiconductor package module 100 may further include other electronic components. For example, the semiconductor package module 100 may have a form in which it has another semiconductor package module mounted thereon. Here, another semiconductor package module may be smaller than that of the semiconductor package module 100.

The substrate 110 may be formed of an insulating material. For example, the substrate 110 may be formed of a material such as a resin, a ceramic, or the like. In addition, the substrate 110 may include circuit patterns (not shown) configuring one or more electric circuits. For example, the substrate 110 may have a first circuit pattern formed on a first surface (upper surface based on FIG. 1) thereof and have a second circuit pattern formed on a second surface (lower surface based on FIG. 1) thereof. Here, the first and second circuit patterns may be connected to each other. For example, the first and second circuit patterns may be connected to each other by via electrodes penetrating through the substrate 110. However, the first and second circuit patterns may not be connected to each other, if necessary.

The substrate 110 may include connection terminals 112. For example, the connection terminals 112 may be formed on the second surface of the substrate 110. In addition, the connection terminals 112 may be formed on only a portion of the substrate 110. For example, the second surface of the substrate 110 may be divided into a first area A1 in which the circuit pattern is formed and a second area A2 in which the circuit pattern is not formed, and the connection terminals 112 may be formed in the second area A2 (See FIG. 3). However, a position in which the connection terminals 112 are formed is not limited to the second area A2. In addition, although the case in which the second area A2 is formed at an edge of the substrate 110 has been shown in FIG. 3, the second area A2 may also be formed in a central portion of the substrate 110, if necessary (for example, the first and second areas A1 and A2 may be reversed).

The connection terminal 112 may be a component for connecting the semiconductor package module 100 to a ground. For example, the connection terminal 112 may be a ground terminal connecting the semiconductor package module 100 and a ground pad of a main circuit board to each other. In addition, the connection terminal 112 may be a component for supplying power to the semiconductor package module 100. For example, the connection terminal 112 may be a power supplying terminal connecting the semiconductor package module 100 and a power supplying part of the main circuit board to each other. In addition, the connection terminal 112 may be a component for transmitting input and output signals of the semiconductor package module 100. For example, the connection terminal 112 may be an input/output signal terminal connecting the semiconductor package module 100 and input and output pads of the main circuit board to each other. In addition, the connection terminal 112 may be a component for transmitting and receiving radio frequency signals. For example, the connection terminal 112 may be a radio frequency signal terminal connecting the semiconductor package module 100 and a communications module of the main circuit board to each other. In addition, a plurality of connection terminals 112 may have the above-mentioned functions, respectively. For example, some of the plurality of connection terminals 112 may be the ground terminals, some thereof may be the power supplying terminals, some thereof may be the input/output signal terminals, and some thereof may be the radio frequency signal terminals. In addition, the others of the plurality of connection terminals 112 may be preliminary terminals for performing additional functions.

The first electronic component 120 may be mounted on the substrate 110. For example, one or more first electronic components 120 may be mounted on the first surface of the substrate 110. In addition, one or more first electronic components 120 may be connected to the first circuit pattern formed on the first surface of the substrate 110. Further, a plurality of first electronic components 120 may be connected to each other through the first circuit pattern. However, all of the first electronic components 120 are not connected to each other through the first circuit pattern. For example, some of the first electronic components 120 may be connected to the second circuit pattern formed on the second surface of the substrate 110. To this end, the first electronic components 120 may be connected to the via electrodes penetrating through the substrate 110.

The second electronic component 130 may be mounted on the substrate 110. For example, one or more second electronic components 130 may be mounted on the second surface of the substrate 110. In addition, one or more second electronic components 130 may be connected to the second circuit pattern formed on the second surface of the substrate 110. Further, a plurality of second electronic components 130 may be connected to each other through the second circuit pattern. Further, one or more second electronic components 130 may be connected to the first electronic component 120 or the first circuit pattern through the via electrode. For example, the first circuit pattern, the second circuit pattern, the first electronic component 120, and the second electronic component 130 may be connected to each other so as to confirm one or more operating circuits or logical circuits.

The third electronic component 140 may be mounted on the substrate 110. For example, the third electronic component 140 may be mounted in the second area A2 of the substrate 110. In addition, the third electronic component 140 may be connected to the connection terminal 112. For example, the third electronic component 140 may be simultaneously connected to one or more connection terminals 112. To this end, the third electronic component 140 may include one or more connection electrodes 142. The third electronic component 140 may be a passive element. For example, the third electronic component 140 may be a resistor (including a chip resistor), an inductor, a capacitor (including a multilayer ceramic capacitor (MLCC)), or the like.

The third electronic component 140 may have a predetermined height h3. For example, the height h3 of the third electronic component 140 may be higher than a height h2 of the second electronic component 130. Therefore, in the case in which the second electronic component 130 and the third electronic component 140 are mounted in parallel with each other on the lower surface of the substrate 110, the third electronic component 140 may further protrude downwardly as compared with the second electronic component 130. This structure may be advantageous in electrically connecting between the third electronic component 140 and an external terminal.

Next, a connection form between the third electronic component 140 and the connection terminal 112 will be described with reference to FIGS. 4 through 6.

The third electronic components 140 may have a form in which they are lengthily extended in one direction of the substrate 110. For example, the third electronic components 140 may have a size at which they may be connected to all of the plurality of connection terminals 112 formed at one side of the substrate 110 (See FIG. 4).

In addition, the third electronic components 140 may have a form in which they are connected to a small number of connection terminals 112. For example, the third electronic components 140 may have a size at which they are connected to one or more connection terminals 112 formed at a specific position (See FIG. 5).

In addition, the third electronic components 140 may have all of the above-mentioned forms. For example, the third electronic components 140 may have different sizes, as shown in FIG. 6. In addition, the respective third electronic components 140 may be individually connected to difference connection terminals 112.

Next, forms of the connection electrode 142 of the third electronic component 140 will be described with reference to FIGS. 7 and 8.

The third electronic component 140 may include the connection electrode 142 connecting the connection terminal 112 and an external terminal to each other. For example, the third electronic component 140 may include one or more connection electrodes 142 extended from a first surface (upper surface based on FIGS. 7 and 8) thereof to a second surface (lower surface based on FIGS. 7 and 8) thereof.

The connection electrode 142 may have any changed form as long as it may connect the connection terminal 112 and the external terminal to each other. For example, the connection electrode 142 may have a form of a via electrode 144 penetrating through the third electronic component 140 (See FIG. 7). Alternatively, the connection electrode 142 may have a form of an external electrode 146 formed on a surface of a third electronic component among the third electronic components 140 (See FIG. 8).

In the semiconductor package module 100 configured as described above, an internal circuit of the semiconductor package module 100 and an internal circuit of the main circuit board may be connected to each other by the third electronic component 140, which may be advantageous in decreasing an electrical signal distance. In addition, the semiconductor package module 100 according to the present exemplary embodiment may be advantageous in improving radio frequency signal characteristics by the third electronic component 140. Further, in the semiconductor package module 100 according to the present exemplary embodiment, the electronic components may be mounted even in an area in which the connection terminals 112 are formed, which may be advantageous in miniaturizing the semiconductor package module 100. Further, in the semiconductor package module 100 according to the present exemplary embodiment, the third electronic component 140 having a capacitor form may be mounted at a power supply terminal adjacent to a ground terminal, which may be advantageous in decreasing noise in the power supply terminal.

Next, another form of the semiconductor package module 100 according to the present exemplary embodiment will be described with reference to FIG. 9.

Another form of the semiconductor package module 100 may include a molded member 160. For example, the semiconductor package module 100 may include the molded member 160 covering the first electronic components 120 or the second electronic components 130.

The molded member 160 may be formed on at least any one of the first and second surfaces of the substrate 110. For example, the molded member 160 may be formed on only the first surface of the substrate 110 so as to cover only the first electronic components 120. Alternatively, the molded member 160 may be formed on both surfaces of the substrate 110 so as to cover all of the first electronic components 120, the second electronic components 130, and the third electronic components 140.

For reference, the molded member 160 may be formed of a resin. However, the molded member 160 is not limited to being formed of the resin.

Hereinafter, a semiconductor package module 100 according to another exemplary embodiment of the present disclosure will be described with reference to FIGS. 10 through 13. For reference, in a description of the present exemplary embodiment, the same components as those of the semiconductor package module according to an exemplary embodiment of the present disclosure described above will be denoted by the same reference numerals, and a description thereof will be omitted.

The semiconductor package module 100 according to the present exemplary embodiment may be different from the semiconductor package module 100 according to an exemplary embodiment of the present disclosure in that it further includes fourth electronic components 150. For example, the semiconductor package module 100 according to the present exemplary embodiment may further include the fourth electronic components 150 connected to the third electronic components 140.

The fourth electronic component 150 may connect the third electronic component 140 and the external terminal to each other. For example, the fourth electronic component 150 may be mounted on one surface (lower surface based on FIG. 10) of the third electronic component 140. Therefore, an entire height (h3+h4) of the third and fourth electronic components 140 and 150 may be increased. Here, the height (h3+h4) may be higher than the height h2 of the second electronic component 130.

One fourth electronic component 150 may be connected to one third electronic component 140 (See FIG. 11). Here, the third and fourth electronic components 140 and 150 may be connected to each other by connection between first and second via electrodes 144 and 154.

In addition, a plurality of fourth electronic components 150 may be connected to one third electronic component 140 (See FIG. 12). Here, the third and fourth electronic components 140 and 150 may be connected to each other by connection between first and second external electrodes 146 and 156.

Meanwhile, although the case in which one fourth electronic component 150 is mounted in a height direction of the third electronic component 140 has been shown in the accompanying drawings, two or more fourth electronic components 150 may also be mounted, if necessary. In addition, the semiconductor package module 100 according to the present exemplary embodiment may include a molded member 160 protecting a plurality of electronic components, as shown in FIG. 13.

The semiconductor package module 100 configured as described above may have a structure in which the third and fourth electronic components 140 and 150 are stacked in one direction, which may be more advantageous in mounting a plurality of electronic components in a limited area.

As set forth above, exemplary embodiments of the present disclosure may be advantageous in miniaturizing the semiconductor package module and may improve performance of the semiconductor package module.

While exemplary embodiments have been shown and described above, it will be apparent to those skilled in the art that modifications and variations could be made without departing from the spirit and scope of the present disclosure as defined by the appended claims.

What is claimed is:

1. A semiconductor package module comprising:
a substrate having one or more connection terminals formed thereon;
first electronic components mounted on a first surface of the substrate;
second electronic components mounted on a second surface of the substrate; and
third electronic components formed on the substrate and including connection electrodes connecting the one or more connection terminals and external terminals to each other.

2. The semiconductor package module of claim 1, wherein the connection terminals are formed in plural rows along an edge of the second surface.

3. The semiconductor package module of claim 1, wherein the connection terminal is a ground electrode terminal.

4. The semiconductor package module of claim 1, wherein the connection terminal is a power supplying terminal.

5. The semiconductor package module of claim 1, wherein the connection terminal is an input/output signal terminal.

6. The semiconductor package module of claim 1, wherein the connection terminal is a radio frequency signal terminal.

7. The semiconductor package module of claim 1, wherein the third electronic component is a passive element.

8. The semiconductor package module of claim 1, wherein the third electronic component is a multilayer ceramic capacitor.

9. The semiconductor package module of claim 1, wherein the third electronic components are connected to a plurality of connection terminals, respectively.

10. The semiconductor package module of claim 1, wherein the third electronic components include a plurality of connection electrodes connected to a plurality of connection terminals, respectively.

11. The semiconductor package module of claim 1, wherein the connection electrode is a via electrode penetrating through a body of a third electronic component among the third electronic components.

12. The semiconductor package module of claim 1, wherein the connection electrode is an external electrode formed on a surface of a third electronic component among the third electronic components.

13. The semiconductor package module of claim 1, further comprising a molded member covering the first and second electronic components.

14. A semiconductor package module comprising:
a substrate having one or more connection terminals formed thereon;
first electronic components mounted on a first surface of the substrate;
second electronic components mounted on a second surface of the substrate;
third electronic components including first connection electrodes connected to the one or more connection terminals; and
fourth electronic components formed on the third electronic components and including second connection electrodes connecting the first connection electrodes and external electrodes to each other.

15. The semiconductor package module of claim 14, wherein the connection terminal is a ground electrode terminal.

16. The semiconductor package module of claim 14, wherein the connection terminal is a power supplying terminal.

17. The semiconductor package module of claim 14, wherein the connection terminal is an input/output signal terminal.

18. The semiconductor package module of claim 14, wherein the connection terminal is a radio frequency signal terminal.

19. The semiconductor package module of claim 14, wherein the third and fourth electronic components are passive elements.

20. The semiconductor package module of claim 14, wherein at least one of the third and fourth electronic components is a multilayer ceramic capacitor.

21. The semiconductor package module of claim 14, wherein the third electronic components are connected to a plurality of connection terminals, respectively.

22. The semiconductor package module of claim 14, wherein the third electronic components include a plurality of first connection electrodes connected to a plurality of connection terminals, respectively.

23. The semiconductor package module of claim 22, wherein a plurality of fourth electronic components are formed on the third electronic components, respectively, so as to be connected to the plurality of first connection electrodes, respectively.

24. The semiconductor package module of claim 14, wherein the first connection electrode is a first via electrode penetrating through a body of a third electronic component among the third electronic components, and
the second connection electrode is a second via electrode penetrating through a body of the fourth electronic component.

25. The semiconductor package module of claim 14, wherein the first connection electrode is a first external electrode formed on a surface of a third electronic component among the third electronic components, and
the second connection electrode is a second external electrode formed along a surface of the fourth electronic component.

26. The semiconductor package module of claim 14, further comprising a molded member covering the first and second electronic components.

27. The semiconductor package module of claim 14, wherein a height of the third electronic component or a height of the fourth electronic component is lower than a height of the first electronic component or a height of the second electronic component.

28. The semiconductor package module of claim 14, wherein a sum of a height of the third electronic component and a height of the fourth electronic component is higher than a height of the first electronic component or a height of the second electronic component.

29. The semiconductor package module of claim 14, wherein the first and second electronic components are formed in a circuit pattern area of the substrate.
